(19) United States
(12) Patent Application Publication
(10) Pub. No.: US 2003/0224254 A1
(43) Pub. Date: Dec. 4, 2003

(54) Method for reducing dimensions between patterns on a photomask

(75) Inventors: Henry Wei-Ming Chung, Hsinchu (TW); Shin-Yi Tsai, Hsinchu (TW); Ming-Chung Liang, Hsinchu (TW)

Correspondence Address: Finnegan, Henderson, Farabow,, Garrett & Dunner, L.L.P., 1300 I Street, N.W., Washington, DC, 20005-3315, US

(73) Assignee: Macronix International Co., Ltd.

(21) Appl. No.: 10/465,848

(22) Filed: Jun. 20, 2003

Related U.S. Application Data
(63) Continuation-in-part of application No. 09/978,546, filed on Oct. 18, 2001.
(60) Provisional application No. 60/390,183, filed on Jun. 21, 2002.

(51) Int. Cl. G03F 1/08; G03F 7/16; G03F 7/20; G03F 7/40

(52) U.S. Cl. 430/5; 430/314; 430/316; 430/950

(57) ABSTRACT

A method for manufacturing a photomask is provided. A transparent substrate is provided and a mask layer is formed thereon. A resist layer is formed on the mask layer and then patterned and defined to define a critical dimension of the photomask. A third layer is deposited over the patterned and defined resist layer to decrease the critical dimension of the photomask. And the third layer and the mask layer are etched afterwards.

### RELATED APPLICATION

This application is a continuation-in-part application of U.S. application Ser. No. 09/978,546, entitled “Method for Reducing Dimensions Between Patterns on a Photoresist,” filed on Oct. 18, 2001, and claims priority to U.S. Provisional Application Serial No. 60/390,183, entitled “Sub-90 nm Space and Hole Patterning Using 248 nm Lithography with Plasma-Polymerization Coating,” filed on Jun. 21, 2002. This application is also related to concurrently-filed U.S. application Ser. No. ______ (Attorney Docket No. 08409.0002-01000), entitled “Method for Reducing Dimensions Between Patterns on a Hardmask,” and U.S. application Ser. No. ______ (Attorney Docket No. 08409.0002-03000), entitled “Method for Reducing Dimensions Between Patterns on a Photoresist.” These related applications are expressly incorporated herein by reference.

### DESCRIPTION OF THE INVENTION

1. Field of the Invention

This invention relates in general to a photomask manufacturing process and, more particularly, to a photomask manufacturing method having reduced dimensions between patterns on a photomask.

2. Background of the Invention

With sub-micron semiconductor manufacturing process being the prevalent technology, the demand for a high-resolution photolithographic process has increased. The resolution of a conventional photolithographic method is primarily dependent upon the wavelength of a light source, which dictates that there be a certain fixed distance between patterns on a photoresist. Distance separating patterns smaller than the wavelength of the light source could not be accurately patterned and defined.

Prior art light sources with lower wavelengths are normally used in a high-resolution photolithographic process. In addition, the depth of focus of a high-resolution photolithographic process is shallower compared to a relative low-resolution photolithographic process. As a result, a photoresist layer having a lower thickness is required for conventional photolithographic methods. However, a photoresist layer having a lower thickness is susceptible to the subsequent etching steps in a semiconductor manufacturing process. This relative ineffective resistance to etching reduces the precision of patterning and defining of a photoresist. These limitations prevent the dimensions of patterns on a photoresist from being reduced.

Furthermore, a photomask is commonly used in the photolithography process, during which a pattern on the photomask is transferred to the photoresist on a substrate. A photomask usually has a transparent substrate with a layer of masking material that blocks light in the photolithography process. A feature size of the photomask determines the feature size of the photoresist patterns. Therefore, reducing the feature size of photomask helps reducing a semiconductor device size.

A conventional method of manufacturing a photomask includes forming the layer of masking material on the transparent substrate, forming a resist layer on the layer of masking material, patterning and defining the resist layer, etching the masking material, and removing the patterned and defined resist layer.

### SUMMARY OF THE INVENTION

In accordance with the present invention, there is provided a method for manufacturing a photomask that includes providing a transparent substrate, forming a mask layer over the substrate, providing a resist layer over the mask layer, patterning and defining the resist layer to define a critical dimension of the photomask, depositing a third layer over the patterned and defined resist layer to decrease the critical dimension of the photomask, etching the third layer, and etching the mask layer.

Also in accordance with the present invention, there is provided a method for manufacturing a photomask that includes providing a transparent substrate, forming a mask layer over the substrate, providing a resist layer over the mask layer, patterning and defining the resist layer to form at least two resist structures, each having a substantially horizontal top and at least one substantially vertical sidewall, and wherein the at least two resist structures are separated by a first space, depositing a layer of photo-insensitive material on the tops and sidewalls of the at least two resist structures, etching the layer of photo-insensitive material, and etching the mask layer.

In one aspect, the step of depositing a layer of photo-insensitive material is performed at a temperature lower than a stability temperature of the patterned and defined resist layer.

Further in accordance with the present invention, there is provided a method for manufacturing a photomask that includes providing a transparent substrate, forming a mask layer over the substrate, providing a resist layer over the mask layer, patterning and defining the resist layer to form at least one resist structure, each having a substantially horizontal top and at least one substantially vertical sidewall, depositing a photo-insensitive material over the at least one resist structure, wherein a first amount of the photo-insensitive material is deposited on the top of the resist structure and a second amount of the photo-insensitive material is deposited on the at least one sidewall of the resist structure, etching the photo-insensitive material and the mask layer, and removing the at least one resist structure.

In one aspect, the first amount is greater than the second amount.

In another aspect, the first amount is less than the second amount.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIGS. 1-3B are cross-sectional views of the semiconductor manufacturing process steps of the present invention; and

FIGS. 4A-4D show cross-sectional views of the photomask manufacturing process steps of the present invention.

### DESCRIPTION OF THE EMBODIMENTS

Reference will now be made in detail to the exemplary embodiments of the invention, examples of which are illustrated in the accompanying drawings. Wherever possible, the same reference numbers will be used throughout the drawings to refer to the same or like parts.

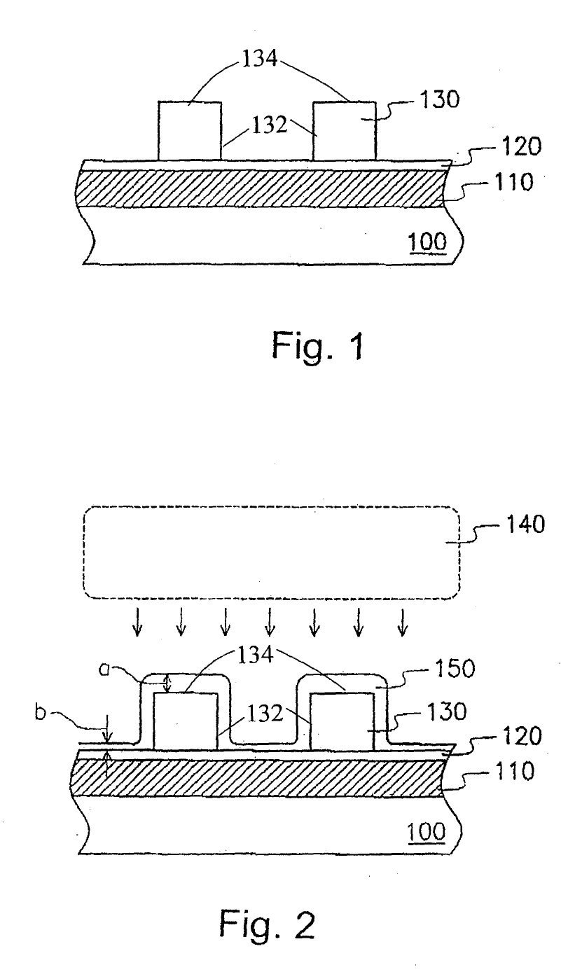

FIGS. 1-3B are cross-sectional views of the semiconductor manufacturing process steps of the present invention. Referring to FIG. 1, the method of the present invention begins by defining a wafer substrate 100. Wafer substrate 100 may be of any known semiconductor substrate material, such as silicon. A first layer 110 is then provided over wafer substrate 100. In one embodiment, first layer 110 is a semiconductor material, such as polysilicon. First layer 110 may also be a dielectric layer or a metal layer. First layer 110 may be deposited over wafer substrate 100 by any known deposition process. In another embodiment, first layer 110 is a dielectric material, in which case first layer 110 may be deposited or grown over wafer substrate 100.

An anti-reflection coating (ARC) layer 120 may optionally be provided over first layer 110 to decrease the reflection from first layer 110 in subsequent manufacturing steps. A photoresist layer 130 is then provided over ARC layer 120. In an embodiment in which an ARC layer is not provided, photoresist layer 130 is deposited overfirst layer 110. Photoresist layer 130 is then patterned and defined using a known photolithographic process to form a patterned and defined photoresist layer having a plurality of photoresist structures 130. Photoresist structures 130 include substantially vertical sidewalls 132 and substantially horizontal tops 134. When first layer 110 is a semiconductor material, photoresist structures 130 functions to form conductors from first layer 110.

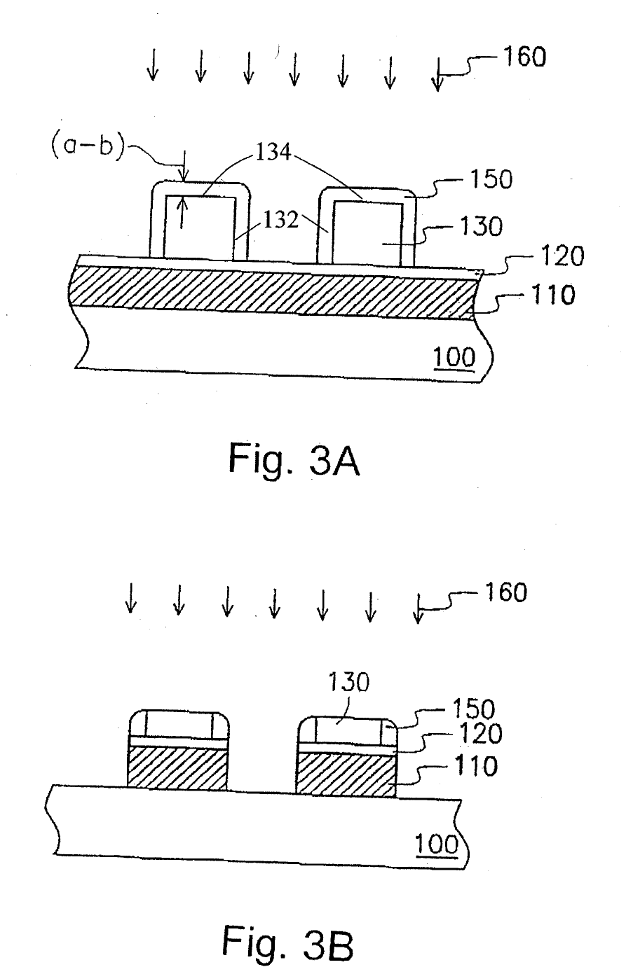

Referring to FIG. 2, a second layer 150 is deposited over the patterned and defined photoresist layer 130 by a known chemical vapor deposition apparatus 140. Known chemical vapor deposition processes include plasma enhanced chemical vapor deposition (PECVD) and low pressure chemical vapor deposition (LPCVD). Second layer 150 may be organic or inorganic, and is photo-insensitive. In one embodiment, second layer 150 is a polymer layer. In another embodiment, second layer 150 is substantially conformal, covering both tops 134 and sidewalls 132 of photoresist structures 130. In one embodiment, an amount of second layer 150 deposited on tops 134 of photoresist structures 130 is substantially greater than an amount adhered to the sidewalls 132. Having a substantially more of second layer 150 deposited on tops 134, photoresist structures 130 become more resistive to subsequent etching steps, thereby preserving the precision of the photolithographic process. In addition, the step of depositing second layer 150 is performed at a temperature lower than a stability temperature of photoresist structures 130. In other words, second layer 150 is deposited at a temperature not affecting the structural stability of photoresist structures 130.

After the deposition of second layer 150, the space between photoresist structures 130 is decreased, for example, from 0.22 microns to 0.02 microns.

In the PECVD process, the pressure used is in the range of approximately 5 mTorr to 30 mTorr. The source power ranges from approximately 900 watts to 1800 watts and the bias power ranges from 0 to 1300 W. The deposition rate is between approximately 3,000 Å per minute and 6,000 Å per minute. In addition, polymer layer 150 comprises at least one hydrocarbon partially substituted by fluorine, the source for forming polymers. The partially-substituted hydrocarbons may be chosen from difluoromethane (CH₂F₂), a mixture of difluoromethane and octafluorobutene (C₄F₈), and a mixture of difluoromethane and trifluoromethane (CHF₃). In one embodiment, when the partially-substituted hydrocarbons include CH₂F₂ only, the thickness “a” of a portion of polymer layer 150 is the same as the thickness “b” of another portion of polymer layer 150.

Moreover, argon (Ar) and carbon monoxide (CO) may be mixed with the gases introduced during the PECVD process. Argon acts as a carrier to enhance etch uniformity of photoresist layer 130 and ARC layer 120. The function of carbon monoxide is to capture fluorine radicals and fluoride ions generated by the fluoro-substituted hydrocarbons. As such, etching of the polymers during the deposition process is prevented, thereby enhancing the deposition rate of polymer layer 150. Oxygen (O₂) and nitrogen (N₂) gases also can be added to the PECVD process. Contrary to the function of the carbon monoxide, the presence of oxygen serves to etch polymer layer 150. Therefore, the deposition rate of polymer layer 150 can be controlled. Also, perfluorohydrocarbons, such as hexafluoroethane (C₂F₆) and tetrafluoromethane (CF₄), can be mixed with the gases combined with the plasma during deposition because these gases, similar to the oxygen gas, etch polymer layer 150.

In one embodiment, when the gases used during deposition of second layer 150 include approximately 10 to 30 sccm of C₄F₈, 10 to 30 sccm of CH₂F₂, 50 to 150 sccm of CO, and 100 to 300 sccm of argon (Ar), the amount of second layer 150 deposited on tops 134 of photoresist structures 130 is substantially greater than the amount adhered to sidewalls 132. In another embodiment, when the gases used during deposition of second layer 150 include approximately 10 to 30 sccm of C₄F₈, 0 to 15 sccm of CH₂F₂, 0 to 50 sccm of CO, and 100 to 300 sccm of argon (Ar), and the bias power is greater than approximately 400 W, the amount of second layer 150 deposited on tops 134 of photoresist structures 130 is substantially less than the amount adhered to sidewalls 132.

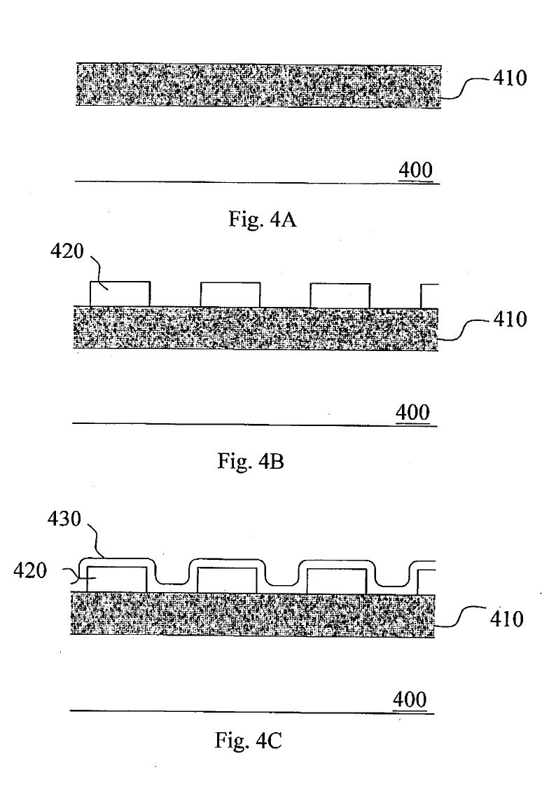

Referring to FIGS. 3A and 3B, second layer 150, photoresist structures 130, ARC layer 120, and first layer 110 are etched anisotropically with a plasma-based dry etching process. The dry etching process uses plasma 160 as etchant. In an embodiment in which “a” is thicker than “b,” the thickness of second layer 150 changes from “a” to “a-b” after second layer 150 deposited over ARC layer 120 is completely etched away. This shows that second layer 150 provides excellent resistance to the plasma etch process and therefore enhances the etching resistance of photoresist structures 130.

As shown in FIG. 3B, when the anisotropic dry etching process continues, second layer 150 acts as an etch stop and remains on the sidewalls of photoresist structures 130. Thus, the dimensions between the patterned photoresist and underlying patterned first layer 110 are reduced. Photoresist structures 130 may be removed using any conventional process.

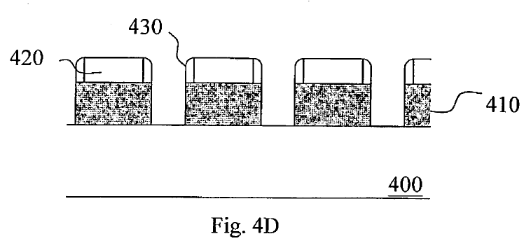

FIGS. 4A-4D show a manufacturing method of a photomask consistent with one embodiment of the present invention. Unless otherwise described hereinafter, the method shown and described in FIGS. 1-3B, including the results and advantages thereof, are the same as the method shown in FIGS. 4A-4D.

Referring to FIG. 4A, a transparent substrate 400 is provided. Substrate 400 may be comprised of glass, such as soda lime glass, borosilicate glass, quartz glass, sapphire, or the like, having a smooth surface. A mask layer 410 is formed on substrate 400. Mask layer 410 may comprise chromium, molyddenum silicide, or other conventional masking material. Referring to FIG. 4B, a resist layer 420 is formed over mask layer 410 and patterned and defined using an electron beam to expose predetermined parts of mask layer 410. One or more resist structures 420 are formed during this step, each of which has a substantially horizontal top and one or more substantially vertical sidewalls.

Referring to FIG. 4C, a third layer material 430 is deposited over the entire surface of the resulted structure including the tops and sidewalls of resist structures 420 and the exposed surface of mask layer 410. Third layer 430 may be deposited with any known chemical vapor deposition process, include plasma enhanced chemical vapor deposition (PECVD) and low pressure chemical vapor deposition (LPCVD). Third layer 430 may be organic or inorganic, and is photo-insensitive. In one embodiment, third layer 430 is a polymer layer, and may be substantially conformal. An anisotropic etching of third layer 430 is performed to remove the inorganic material deposited on the exposed surface of mask layer 410, as shown in FIG. 4D. Third layer 430 deposited on the sidewalls is not removed or is only partially removed. The resulted resist structures 420 with third layer material 430 on the sidewalls narrows the critical dimension defined as the minimal feature size of the photomask.

In one embodiment, the one or more resist structures 420 comprise at least two resist structures separated by a space. As shown in FIG. 4D, the space between the at least two resist structures is reduced by the inorganic material deposited on the sidewalls of the structures.

In another embodiment, an amount of the inorganic material deposited on the tops of resist structures 420 is substantially greater than an amount of the inorganic material deposited on the sidewalls of resist structures 420. In yet another embodiment, an amount of the inorganic material deposited on the tops of resist structures 420 is substantially less than an amount of the inorganic material deposited on the sidewalls of resist structures 420.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A photomask manufacturing method, comprising:
providing a transparent substrate;
forming a mask layer over the substrate;
providing a resist layer over the mask layer;
patterning and defining the resist layer to define a critical dimension of the photomask;
depositing a third layer over the patterned and defined resist layer to decrease the critical dimension of the photomask;
etching the third layer; and
etching the mask layer.

2. The method as claimed in claim 1, wherein the third layer is photo-insensitive.

3. The method as claimed in claim 1, wherein the third layer is inorganic.

4. The method as claimed in claim 1, wherein the third layer comprises polymer.

5. The method as claimed in claim 1, wherein the third layer is substantially conformal.

6. The method as claimed in claim 1, wherein the mask layer comprises one of chromium or molyddenum silicide.

7. The method as claimed in claim 1, wherein the transparent substrate comprises one of soda lime glass, borosilicate glass, quartz glass, or sapphire.

8. The method as claimed in claim 1, wherein the step of depositing a third layer is performed at a temperature lower than a stability temperature of the patterned and defined resist layer.

9. A photomask manufacturing method, comprising:
providing a transparent substrate;
forming a mask layer over the substrate;
providing a resist layer over the mask layer;
patterning and defining the resist layer to form at least two resist structures, each having a substantially horizontal top and at least one substantially vertical sidewall, and wherein the at least two resist structures are separated by a first space;
depositing a layer of photo-insensitive material on the tops and sidewalls of the at least two resist structures;
etching the layer of photo-insensitive material; and
etching the mask layer.

10. The method as claimed in claim 9, wherein the photo-insensitive material comprises polymer.

11. The method as claimed in claim 9, wherein the step of depositing a layer of photo-insensitive material is performed at a temperature lower than a stability temperature of the patterned and defined resist layer.

12. The method as claimed in claim 9, wherein the step of etching the layer of photo-insensitive material etches at most a portion of the photo-insensitive material deposited on the sidewalls of the at least two structures, the at least two resist structures with remaining photo-insensitive material on the sidewalls being separated by a second space, and wherein the first space is greater than the second space.

13. A photomask manufacturing method, comprising:
providing a transparent substrate;
forming a mask layer over the substrate;
providing a resist layer over the mask layer;
patterning and defining the resist layer to form at least one resist structure, each having a substantially horizontal top and at least one substantially vertical sidewall;
depositing a photo-insensitive material over the at least one resist structure, wherein a first amount of the photo-insensitive material is deposited on the top of the resist structure and a second amount of the photo-insensitive material is deposited on the at least one sidewall of the resist structure;
etching the photo-insensitive material and the mask layer; and
removing the at least one resist structure.

14. The method as claimed in claim 13, wherein the first amount of photo-insensitive material is greater than the second amount of photo-insensitive material.

15. The method as claimed in claim 14, wherein the step of depositing a photo-insensitive material comprises depositing a layer of polymer with a mixture of gases, wherein the mixture of gases comprise approximately 10 to 30 sccm of C₄F₈, 10 to 30 sccm of CH₂F₂, 50 to 150 sccm of CO, and 100 to 300 sccm of argon.

16. The method as claimed in claim 13, wherein the step of depositing a layer of photo-insensitive material is performed at a temperature lower than a stability temperature of the patterned and defined resist layer.

17. The method as claimed in claim 13, wherein the first amount of photo-insensitive material is less than the second amount of photo-insensitive material.

18. The method as claimed in claim 17, wherein depositing a photo-insensitive material comprises depositing a layer of polymer with a mixture of gases, wherein the mixture of gases comprise approximately 10 to 30 sccm of C₄F₈, 0 to 15 sccm of CH₂F₂, 0 to 50 sccm of CO, and 100 to 300 sccm of argon.

19. A semiconductor manufacturing method, comprising:
providing a transparent substrate;
forming a mask layer over the substrate;
providing a resist layer over the mask layer;
patterning and defining the resist layer to form at least two resist structures, wherein each of the resist structures includes substantially vertical sidewalls and a substantially horizontal top, and wherein the resist structures are separated by a first space;
depositing a photo-insensitive layer on the sidewalls of the resist structures such that the resist structures with the photo-insensitive layer on the sidewalls thereof are separated by a second space, wherein the first space is greater than the second space; and
anisotropic etching of the photo-insensitive layer.

20. The method as claimed in claim 19, further comprising anisotropic etching the first layer using the resist structures and the photo-insensitive layer on the sidewalls of the resist structures as a mask to form at least two mask layer structures separated by a third space, and wherein the third space is narrower than the first space.

21. The method as claimed in claim 19, wherein the mask layer comprises one of chromium or molyddenum silicide.

22. The method as claimed in claim 19, further comprising a step of depositing an anti-reflection coating over the mask layer.

23. The method as claimed in claim 19, wherein the photo-insensitive layer comprises polymer.

24. The method as claimed in claim 19, wherein the step of depositing a photo-insensitive layer is performed with plasma enhanced chemical vapor deposition at a rate between approximately 3000 Å per minute and 6000 Å per minute.

25. The method as claimed in claim 19, wherein the step of depositing a photo-insensitive layer is performed at a temperature lower than a stability temperature of the patterned and defined photoresist layer.

26. A semiconductor manufacturing method, comprising:
defining a transparent substrate;
depositing a mask layer over the transparent substrate;
providing a resist layer over the mask layer;
patterning and defining the resist layer to form at least two resist structures, wherein each resist structure includes at least one substantially vertical sidewall and one substantially horizontal top, and wherein the resist structures are separated by a first space;
depositing a photo-insensitive material over the at least two resist structures and the mask layer, wherein an amount of the photo-insensitive material deposited on the top of the resist structures is substantially greater than an amount of the photo-insensitive material deposited on the at least one sidewall of the resist structures, wherein the resist structures with the photo-insensitive layer on the sidewalls thereof are separated by a second space, and wherein the first space is greater than the second space;
etching the photo-insensitive material and the mask layer; and
removing the at least two resist structures.
